(19) United States
(12) Patent Application Publication
(10) Pub. No.: US 2006/0145712 A1
(43) Pub. Date: Jul. 6, 2006

(54) Contact-type film probe

(76) Inventors: Chih Yuan Wang, Shengang Township (TW); Heng Yi Chang, Taipei City (TW); Ya Lin Hsu, Dacheng Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/028,636

(22) Filed: Jan. 5, 2005

(51) Int. Cl. G01R 31/02

(52) U.S. Cl. 324/754

(57) ABSTRACT

A contact-type film probe including a plastic substrate and multiple signal lines arranged on one face of the substrate. A silver conductive layer is disposed corresponding to each signal line. A contact conductive layer is further disposed at one end of each signal line for contacting with the wires of the liquid crystal display. By means of the silver-made conductive layer, the contact impedance is reduced to enhance the transmission efficiency of the signal. In addition, through silver mirror reaction of the silver-made conductive layer, the mirror-face reflectivity is enhanced so as to enhance the accuracy of reflective alignment. Therefore, the using efficiency of the contact-type film probe is increased.

### BACKGROUND OF THE INVENTION

The present invention is related to a film probe for testing liquid crystal display, and more particularly to a contact-type film probe, in which a silver-made conductive layer is disposed for reducing the contact impedance to enhance the transmission efficiency of the signal. Therefore, the using efficiency of the contact-type film probe is increased.

In a conventional contact-type soft film probe structure, multiple one-to-one straight film probes are directly made on a specific tool according to the wire layout of a liquid crystal display. The probes directly contact with the wires of the liquid crystal display. After contacted, the test signal will be input via the probes to activate the liquid crystal display. According to the state of display, it can be judged whether the liquid crystal display is good or bad.

FIGS. 3 and 4 show a conventional contact-type soft film probe. Multiple signal lines 82 are arranged on one face of a plastic substrate 81 according to wire layout of a liquid crystal display. A contact conductive layer 83 is disposed at one end of each signal line 82 to form a probe. The other section of the signal line 82 free from the copper contact conductive layer 83 is coated with an insulating layer 84.

The thickness of each layer of the film probe is in the grade of micron so that the thickness of the film probe as a whole is still very thin. Accordingly, when contacting the film probe with the wire 91 of the liquid crystal display 9 as shown in FIG. 5, it is necessary to slightly apply a pressure onto the probe, whereby the contact conductive layers 83 of the film probe can truly contact with the wires 91 of the liquid crystal display. However, the contact conductive layers 83 are generally made of copper foil material. Therefore, during contacting, due to friction, the contact impedance of the copper contact conductive layers 83 will be relatively high. As a result, the transmission of the signal will be poor. Accordingly, the test result of the liquid crystal display will be affected.

Furthermore, when the film probe contacts with the wires of the liquid crystal display, the copper contact conductive layers 83 have poorer mirror-face reflective effect. Therefore, the alignment between the contact conductive layers 83 and the wires of the liquid crystal display can be hardly performed by way of reflective alignment. As a result, it is hard to truly align the contact conductive layers 83 with the wires of the liquid crystal display. Therefore, the signal cannot be normally transmitted to the wires of the liquid crystal display. This will make the liquid crystal display unable to display pictures or lead to poor display of the pictures. Accordingly, the test result of the liquid crystal display will be affected.

### SUMMARY OF THE INVENTION

It is therefore a primary object of the present invention to provide a contact-type film probe in which a silver-made conductive layer is disposed corresponding to each signal line for reducing the contact impedance to enhance the transmission efficiency of the signal. Therefore, the using efficiency of the contact-type film probe is increased.

It is a further object of the present invention to provide the above contact-type film probe in which through silver mirror reaction of the silver-made conductive layer, the size of the particles is minified and the evenness is enhanced. Therefore, the mirror-face reflectivity is enhanced so as to enhance the accuracy of reflective alignment.

According to the above object, the contact-type film probe of the present invention includes a plastic substrate and multiple signal lines arranged on one face of the substrate. A conductive layer is disposed corresponding to each signal line. A contact conductive layer is further disposed at one end of each signal line and electrically connected with the signal line. The other section of each signal line free from the contact conductive layer is coated with an insulating layer.

The present invention can be best understood through the following description and accompanying drawings wherein:

### BRIEF DESCRIPTION OF THE DRAWINGS

FIG. 1 is a sectional view showing the structure of the present invention;

FIG. 2 is a sectional view showing the structure of a second embodiment of the present invention;

FIG. 3 is a sectional view showing the structure of a conventional contact-type soft film probe;

FIG. 4 is a sectional view in another direction, showing the structure of the conventional contact-type soft film probe; and

FIG. 5 is a sectional view showing the use of the conventional contact-type soft film probe.

### DETAILED DESCRIPTION OF THE PREFERRED EMBODIMENT

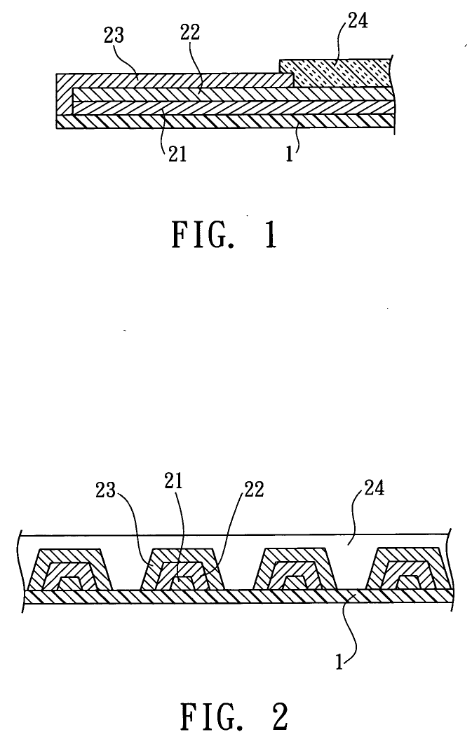

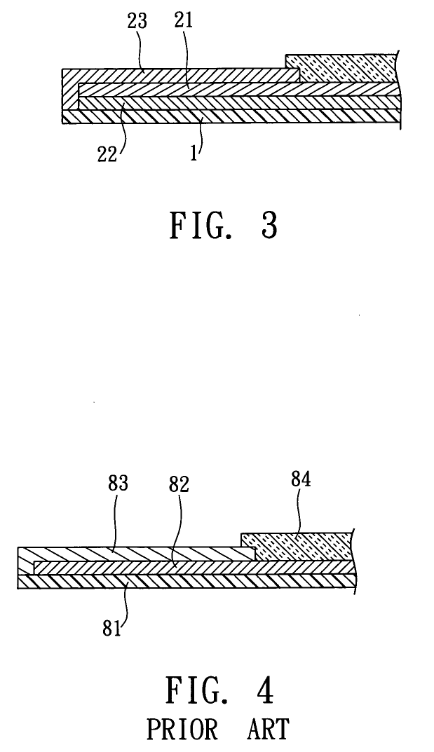

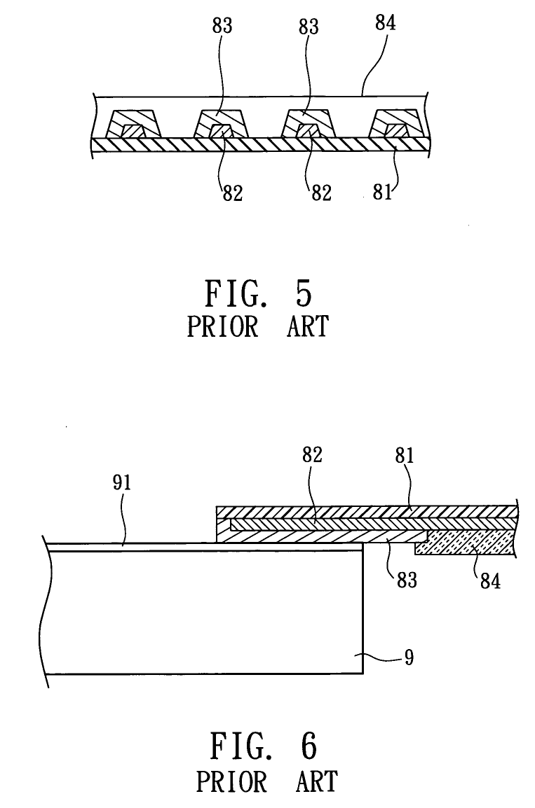

Please refer to FIG. 1. The contact-type film probe of the present invention includes a plastic substrate 1. Multiple signal lines 21 are arranged on one face of the substrate 1. A conductive layer 22 is disposed corresponding to each signal line 21. A contact conductive layer 23 is further disposed at one end of each conductive layer 22 for contacting with the wires of the liquid crystal display. The other section of each conductive layer 22 free from the contact conductive layer 23 is coated with an insulating layer 24.

The substrate 1 can be made of any of polyimide, PET, PC, PMMA and polysulfone.

Importantly, the conductive layer 22 is made of silver or silver alloy for reducing contact impedance and enhancing the transmission efficiency of the signal. Therefore, the problem of higher contact impedance of the copper contact conductive layers of the conventional technique caused by friction can be solved.

The data of impedance test of silver and copper are shown in the following table:

| substrate | constant current (A) | voltage (V) | deposition time (Min) |
|---|---|---|---|
| PI/mone1/Cu | 6 | 1.85 | 10 |
| PI/mone1/Ag | 6 | 1.69 | 10 |

wherein the copper plate and silver plate are negative electrodes and the electroplating is performed in aqueous solution of cupric sulfate.

It can be known from the table that the impedance of silver is 9.5% lowered so that silver is a better conductor.

Furthermore, the conductive layer 22 is made of silver or silver alloy. Therefore, through silver mirror reaction, the particles can be minified and the evenness can be enhanced. Please refer to Attachment 1. In Attachment 1, picture A is an electronic microscopic picture of the signal line of prior art. The size of the particle is about within 29˜49 μm. Picture B is an electronic microscopic picture of the conductive layer of the present invention. The size of the particle is about within 18˜30 μm and is evener. Therefore, the mirror-face reflectivity is enhanced. Accordingly, the film probe can be aligned with the wires of the liquid crystal display by way of reflective alignment so as to enhance the accuracy of alignment. Therefore, the problem that the signal cannot be normally transmitted to the wires of the liquid crystal display due to untrue alignment can be obviated.

In conclusion, in the present invention, the silver conductive layer 22 is additionally disposed to lower contact impedance and enhance the transmission efficiency of the signal. Therefore, the using efficiency of the contact-type film probe is increased. Moreover, through silver mirror effect, the mirror-face reflectivity is enhanced so as to enhance the accuracy of reflective alignment.

FIG. 2 shows a second embodiment of the present invention, in which the conductive layer 22 is disposed between the signal line 21 and the contact conductive layer 23. This can achieve the same effect as the first embodiment.

The above embodiments are only used to illustrate the present invention, not intended to limit the scope thereof. Many modifications of the above embodiments can be made without departing from the spirit of the present invention.

1. A contact-type film probe comprising a plastic substrate and multiple signal lines arranged on one face of the substrate, a conductive layer being disposed corresponding to each signal line and disposed between each signal line and the substrate, a contact conductive layer being further disposed at one end of each signal line and electrically connected with the signal line, the other section of each signal line free from the contact conductive layer being coated with an insulating layer.

2. The contact-type film probe as claimed in claim 1, wherein the substrate is made of any of polyimide, PET, PC, PMMA and polysulfone.

3. The contact-type film probe as claimed in claim 1, wherein the conductive layer is made of silver or silver alloy.

4-5. (canceled)
